(19) United States
(12) Patent Application Publication
(10) Pub. No.: US 2026/0231682 A1
(43) Pub. Date: Aug. 6, 2026

(54) COMPOSITE SUBSTRATE AND PREPARATION METHOD THEREFOR

(71) Applicant: Tiantong Ruihong Technology Co., Ltd, Jiaxing City, Zhejiang Province (CN)

(72) Inventors: Junyao Shen, Jiaxing City, Zhejiang Province (CN); Wenfeng Yao, Jiaxing City, Zhejiang Province (CN); Jiahui Xu, Jiaxing City, Zhejiang Province (CN)

(21) Appl. No.: 19/000,822

(22) Filed: Dec. 24, 2024

(30) Foreign Application Priority Data
Dec. 25, 2023 (CN) 202311786539.X

(51) Int. Cl. H10N 30/072; H10P 90/00

(52) U.S. Cl. CPC H10N 30/072; H10P 90/1916

(57) ABSTRACT

The present disclosure provides a preparation method for the composite substrate, wherein the preparation method includes: performing first bonding between a first wafer and a second wafer, and performing a first thinning treatment on the second wafer to obtain a composite wafer; and performing second bonding between one side of the second wafer of the composite wafer and a piezoelectric wafer, and performing a second thinning treatment on the piezoelectric wafer to obtain the composite substrate. At most three single crystal layers can be realized by the preparation method for the composite substrate and the composite substrate. By using the anisotropy regulation for each layer of material, the more plentiful and more accurate performance regulation can be realized, so as to solve the problems that cannot be solved in the prior composite substrate, so that the device performance can be further improved.

### CROSS-REFERENCE TO RELATED APPLICATION

The present disclosure claims priority to Chinese patent Application No. 202311786539X, filed with the Chinese Patent Office on December 25, 2023, entitled “COMPOSITE SUBSTRATE AND PREPARATION METHOD THEREFOR”, the entire contents of which are incorporated herein by reference.

### TECHNICAL FIELD

The present disclosure belongs to the technical field of functional materials, and relates to a composite substrate and a preparation method therefor.

### BACKGROUND ART

The composite substrate is usually prepared by using the bonding technique, and is widely favored due to its unique performance advantage. With the continuous progress of the bonding technique, the composite substrate is more and more widely used in integrated circuits, microelectromechanical systems, chip integration, and other fields.

The lithium niobate and lithium tantalate have larger piezoelectric constants, higher electro-optic coefficients, and quadratic nonlinear coefficients, which are commonly used in fields of both the acoustic device and optical device. The piezoelectric material on insulator (POI) based on the lithium-niobate or lithium-tantalate thin films is a typical composite substrate, which is prepared by the piezoelectric wafer and the support substrate wafer such as silicon, sapphire, and spinel by using the bonding technique. One or more layers of middle layer materials with specific functions can be arranged between the piezoelectric wafer and support substrate wafer by using a coating method, or it may not be provided. Since the POI composite substrate has an excellent waveguide effect and at the same time has a better quality factor, a faster heat dissipation rate, and a better temperature stability, such that it has become research hotspots in the field of acoustic filters, electro-optic modulators, etc.

However, the prior POI composite substrate still has some drawbacks. The support substrate materials such as silicon, sapphire, spinel, and silicon carbide, and the middle layer materials such as silicon dioxide commonly used in the POI composite substrate all have convex slowness, which will lead to the whole slowness of the device to be convex, so as to bring the problem of spurious response in transverse modes. If the support substrate material is adjusted to a quartz having a specific cutting angle with the concave slowness, the whole performance such as device quality factor will be reduced. Therefore, the POI composite substrates and preparation methods (such as CN111477543A and CN111834520A) in the prior studies still have possibility for optimization.

### SUMMARY

In order to solve technical problems in the prior art, the present disclosure provides a composite substrate and a preparation method therefor, wherein at most three single crystal layers can be realized by the preparation method for the composite substrate and the composite substrate. By using the anisotropy regulation for each layer of material, the more plentiful and more accurate performance regulation can be realized, so as to solve the problems that cannot be solved in the prior composite substrate, so that the device performance can be further improved.

In order to achieve the above technical effects, the present disclosure adopts the following technical solutions.

One object of the present disclosure is to provide a preparation method for the composite substrate, wherein the preparation method includes:

- performing first bonding between a first wafer and a second wafer, and performing a first thinning treatment on the second wafer to obtain a composite wafer; and

performing second bonding between one side of the second wafer of the composite wafer and a piezoelectric wafer and performing a second thinning treatment on the piezoelectric wafer to obtain the composite substrate.

As a preferred technical solution of the present disclosure, the first wafer is a substrate wafer.

As a preferred technical solution of the present disclosure, at least one middle layer is prepared on one side of the first wafer before the first bonding.

As a preferred technical solution of the present disclosure, the first bonding is performed between the second wafer and one side of the middle layer of the first wafer.

As a preferred technical solution of the present disclosure, the first thinning treatment includes:

injecting ions at one side of the second wafer before the first bonding, so as to obtain an ion damage layer;

performing the first bonding between one side of the ion damage layer of the second wafer and the first wafer; and

annealing and stripping after the first bonding.

As a preferred technical solution of the present disclosure, the first thinning treatment includes: performing grinding thinning for the first wafer after the first bonding.

As a preferred technical solution of the present disclosure, at least one middle layer is prepared on one side of the second wafer before the second bonding.

As a preferred technical solution of the present disclosure, the second thinning treatment includes:

injecting ions at one side of the piezoelectric wafer before the second bonding, so as to obtain an ion damage layer;

performing the second bonding between one side of the ion damage layer of the piezoelectric wafer and the composite wafer; and

annealing and stripping after the second bonding.

As a preferred technical solution of the present disclosure, the second thinning treatment includes: performing grinding thinning for the piezoelectric wafer after the second bonding.

Another object of the present disclosure is to provide a composite substrate, wherein the composite substrate is prepared by the preparation method for the composite substrate provided by the above object.

Compared with the prior art, the present disclosure at least has the following beneficial effects.

(1) The composite substrate and the preparation method therefor provided by the present disclosure realize at most three single crystal layers. By using the anisotropy regulation for each layer of the material, the more plentiful and more accurate performance regulation can be realized, so as to solve the problems that cannot be solved in the prior composite substrate, so that the device performance can be further improved.

(2) The present disclosure provides a composite substrate and the preparation method therefor. Besides playing a supporting role, the support substrate can also improve quality factor of the device, realize the waveguide effect, and accelerate the heat dissipation of the device. The composite substrate has a higher transmission efficiency and a lower transmission loss during the electro-optic and acoustic-electric transmission processes by realizing the waveguide effect.

(3) The present disclosure provides a composite substrate and the preparation method therefor. In the prior composite substrate, it is difficult to both ensure the improvement of the quality factor of the device and other whole performances, and to avoid the occurrence of spurious response in transverse modes and other difficult problems. However, by using the preparation method for the composite substrate and the composite substrate of the present disclosure, when the support substrate is a conventional substrate material, such as silicon, sapphire, or silicon carbide, and the single-crystal functional layer is specific tangential quartz, the above technical problems can be solved, so as to comprehensively improve the device performance.

(4) The present disclosure provides a composite substrate and the preparation method therefor, which will generate great application values for acoustic devices and optical devices with higher performance.

### BRIEF DESCRIPTION OF DRAWINGS

FIG. 1 is a schematic flow diagram of a preparation method for a composite substrate provided by Example 1;

FIG. 2 is a schematic flow diagram of a preparation method for a composite substrate provided by Example 2;

FIG. 3 is a schematic flow diagram of a preparation method for a composite substrate provided by Example 3;

FIG. 4 is a schematic flow diagram of a preparation method for a composite substrate provided by Example 4; and

FIG. 5 shows a structure schematic diagram of composite substrates prepared by Examples 1-4.

Reference numbers: 1-first wafer, 2-second wafer, 3 and 7-ion damage layer, 4-single-crystal functional layer, 5-composite wafer, 6-piezoelectric wafer, 8-piezoelectric layer, 101 and 501-middle layer.

The present disclosure is further described in detail below. However, the following examples are only simple examples of the present disclosure and do not represent or limit the scope of protection of the claims of the present disclosure. The scope of protection of the present disclosure is governed by the claims.

### DETAILED DESCRIPTION OF EMBODIMENTS

The technical solutions of the present disclosure are further below in conjunction with the drawings and specific embodiments.

The specific embodiment of the present disclosure is to provide a preparation method for the composite substrate, wherein the preparation method includes:

performing first bonding between a first wafer and a second wafer, and performing a first thinning treatment on the second wafer to obtain a composite wafer; and

performing second bonding between one side of the second wafer of the composite wafer and a piezoelectric wafer and performing a second thinning treatment on the piezoelectric wafer to obtain the composite substrate.

In the present disclosure, the composite substrate prepared by the preparation method has excellent comprehensive performances, wherein the support substrate can play a supporting role, improve the device quality factor, realize the waveguide effect, and accelerate the heat dissipation of the device; the single-crystal functional layer is different from the polycrystalline layer formed by the coating process, and can realize the anisotropy and precise regulation, so as to solve the remaining problems remaining in the prior art; and the piezoelectric layer is also a single-crystal state, and due to its excellent electroacoustic property and electro-optic property, the composite substrate of the present disclosure can be used in the acoustic device or the optical device.

In a specific embodiment of the present disclosure, the first wafer and the second wafer are washed before performing the preparation method. The washing method is commonly used in the wafer substrate preparation, wherein the specific process and parameters are not specifically limited herein.

In a specific embodiment of the present disclosure, if a middle layer is prepared on one side of the first wafer, the surface of the middle layer is polished before the first bonding. The method of the polishing treatment can be chemical-mechanical polishing.

In a specific embodiment of the present disclosure, the preparation method for the middle layer can be the coating process. The coating process can be magnetron sputtering, electron beam deposition, and chemical vapor deposition, etc. The materials and specific parameters of the coating process can be referred to the commonly used materials and methods in the wafer substrate preparation, wherein the specific materials and parameters are not specifically limited herein.

In a specific embodiment of the present disclosure, the method of the first bonding can be plasma-activated bonding, high-vacuum surface-activated bonding, anode bonding, polymer bonding, or hybrid bonding, etc. The bonding environment can be vacuum or atmospheric pressure, and the bonding temperature is larger than or equal to the room temperature. The present disclosure does not limit the bonding process, and a suitable bonding process can be selected according to the actual situation.

In a specific embodiment of the present disclosure, the injection ions used in the ion injection process in the first thinning treatment can be any one or a combination of at least two of the hydrogen ion, helium ion, oxygen ion, or neon ion. The energy injected by the ions controls a depth of the ion damage layer, which can be 10~2000 keV, such as 10 keV, 20 keV, 50 keV, 100 keV, 200 keV, 500 keV, 1000 keV, 1200 keV, 1500 keV, 1800 keV, or 2000 keV. The dosage of the ion injection can be 1×10¹⁶~2×10¹⁷ ions/cm², such as 1×10¹⁶ ions/cm², 2×10¹⁶ ions/cm², 5×10¹⁶ ions/cm², 8×10¹⁶ ions/cm², 1×10¹⁷ ions/cm², 1.2×10¹⁷ ions/cm², 1.5×10¹⁷ ions/cm², 1.8×10¹⁷ ions/cm², or 2×10¹⁷ ions/cm². It is not only limited to the listed values, and other unlisted values in the above value ranges are also applicable.

In a specific embodiment of the present disclosure, the annealing and stripping in the first thinning treatment can be performed in a vacuum environment, a nitrogen atmosphere, or an inert gas atmosphere. The annealing temperature can be 80~800°C, such as 80°C, 100°C, 150°C, 200°C, 250°C, 300°C, 400°C, 500°C, 600°C, 700°C, or 800°C. The annealing duration can be 1~300h, such as 1h, 2h, 5h, 10h, 15h, 20h, 30h, 50h, 100h, 150h, 200h, 250h, or 300h. It is not only limited to the listed values, and other unlisted values in the above value ranges are also applicable. The present disclosure does not limit the annealing process, and a suitable annealing process can be selected according to the actual situations.

In a specific embodiment of the present disclosure, the surface of one side of the second wafer of the composite wafer is polished after the first thinning treatment. The method of the polishing treatment can be chemical-mechanical polishing.

In a specific embodiment of the present disclosure, if a middle layer is prepared on one side of the second wafer of the composite wafer, the surface of the middle layer is polished before the second bonding. The method of the polishing treatment can be chemical-mechanical polishing.

In a specific embodiment of the present disclosure, the method of the second bonding can be plasma-activated bonding, high-vacuum surface-activated bonding, anode bonding, polymer bonding, or hybrid bonding, etc. The bonding environment can be vacuum or atmospheric pressure, and the bonding temperature is larger than or equal to the room temperature. The present disclosure does not limit the bonding process, and a suitable bonding process can be selected according to the actual situations.

In a specific embodiment of the present disclosure, the injection ions used in the ion injection process in the second thinning treatment can be any one or a combination of at least two of the hydrogen ion, helium ion, oxygen ion, or neon ion. The energy injected by the ions controls the depth of the ion damage layer, which can be 10~2000 keV, such as 10 keV, 20 keV, 50 keV, 100 keV, 200 keV, 500 keV, 1000 keV, 1200 keV, 1500 keV, 1800 keV, or 2000 keV. The dosage of the ion injection can be 1×10¹⁶~2×10¹⁷ ions/cm², such as 1×10¹⁶ ions/cm², 2×10¹⁶ ions/cm², 5×10¹⁶ ions/cm², 8×10¹⁶ ions/cm², 1×10¹⁷ ions/cm², 1.2×10¹⁷ ions/cm², 1.5×10¹⁷ ions/cm², 1.8×10¹⁷ ions/cm², or 2×10¹⁷ ions/cm². It is not only limited to the listed values, and other unlisted values in the above value ranges are also applicable.

In a specific embodiment of the present disclosure, the annealing and stripping in the second thinning treatment can be performed in the vacuum environment, nitrogen atmosphere, or inert gas atmosphere. The annealing temperature can be 80~800°C, such as 80°C, 100°C, 150°C, 200°C, 250°C, 300°C, 400°C, 500°C, 600°C, 700°C, or 800°C. The annealing duration can be 1~300h, such as 1h, 2h, 5h, 10h, 15h, 20h, 30h, 50h, 100h, 150h, 200h, 250h, or 300h. It is not only limited to the listed values, and other unlisted values in the above value ranges are also applicable. The present disclosure does not limit the annealing process, and a suitable annealing process can be selected according to the actual situations.

In a specific embodiment of the present disclosure, the surface of one side of the piezoelectric wafer is polished after the second thinning treatment. The method of the polishing treatment can be chemical-mechanical polishing.

In a specific embodiment of the present disclosure, all of the above polishing treatments can be single-sided polishing or double-sided polishing.

In a specific embodiment of the present disclosure, the object of the chemical-mechanical polishing treatment is to remove the residual damage layer, to control the thickness of the film to reach a preset thickness, and to realize the surface flattening. Generally, the surface roughness Ra after the chemical-mechanical polishing treatment should be smaller than 1nm, or other process technologies such as chemical corrosion can also be used to realize the same object.

In a specific embodiment of the present disclosure, the first thinning treatment and the second thinning treatment can also individually use the method of grinding thinning. The grinding thinning treatment can be completed at once or several times, and the thickness of the film after the grinding treatment should be slightly thicker than the preset thickness.

The specific embodiment of the present disclosure provides a composite substrate, wherein the composite substrate is prepared by the preparation method for the composite substrate above.

In a specific embodiment of the present disclosure, the composite substrate includes a support substrate (first wafer), a first middle layer, a single-crystal functional layer (second wafer), a second middle layer, and a piezoelectric layer (piezoelectric wafer) arranged in sequence.

In a specific embodiment of the present disclosure, the composite substrate includes the support substrate (first wafer), the first middle layer, the single-crystal functional layer (second wafer), and the piezoelectric layer (piezoelectric wafer) arranged in sequence.

In a specific embodiment of the present disclosure, the composite substrate includes the support substrate (first wafer), the single-crystal functional layer (second wafer), the second middle layer, and the piezoelectric layer (piezoelectric wafer) arranged in sequence.

In a specific embodiment of the present disclosure, the composite substrate includes the support substrate (first wafer), the single-crystal functional layer (second wafer), and the piezoelectric layer (piezoelectric wafer) arranged in sequence.

In a specific embodiment of the present disclosure, the material of the support substrate (the first wafer) can be any one of high-resistance silicon, sapphire, spinel, silicon carbide, or diamond, or other materials can be selected according to the actual demands, and the present disclosure is not limited thereto.

In a specific embodiment of the present disclosure, the material of the single-crystal functional layer (the second wafer) can be any one of quartz, yttrium aluminum garnet, or magnesium oxide, or other materials can be selected according to the actual demands, and the present disclosure is not limited thereto. The cutting type and cutting angle of the single-crystal functional layer can be selected according to the requirement to the device, and the present disclosure is not limited thereto. The thickness of the single-crystal functional layer can be 30nm~300μm.

In a specific embodiment of the present disclosure, the material of the piezoelectric layer (the piezoelectric wafer) can be any one of lithium tantalate, lithium niobate, zinc oxide, or aluminum nitride, or other piezoelectric materials can be selected according to the actual demands, and the present disclosure is not limited thereto. The cutting type and cutting angle of the piezoelectric layer can be selected according to the requirement to the device, and the present disclosure is not limited thereto. The thickness of the piezoelectric layer can be 30nm~300μm.

In order to better illustrate the present disclosure and to facilitate understanding of the technical solutions of the present disclosure, exemplary but non-limiting embodiments of the present disclosure are as follows.

### Example 1

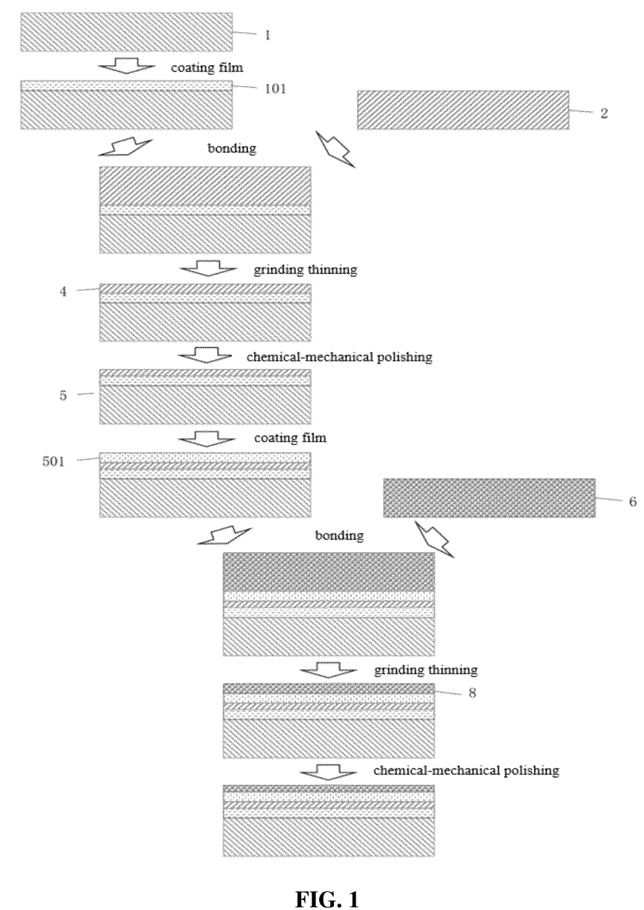

The present embodiment provided a preparation method for a composite substrate, as shown in FIG. 1 (the middle layer 101 and the middle layer 501 were not prepared), wherein the preparation method was as follows.

The first wafer 1 and the second wafer 2 were washed, wherein the first wafer 1 was a double-polished c-face sapphire wafer, and the second wafer 2 was a double-polished 69°Y-90°X quartz wafer.

The first bonding was performed between the first wafer 1 and the second wafer 2. The first bonding was performed by using a high-vacuum surface-activation bonding method, i.e., the bonding surfaces of the first wafer 1 and the second wafer 2 were bombarded by argon atoms or argon ions, so as to remove pollutants and activate the surface, and then two bonding surfaces were tightly attached to realizing the bonding, wherein the bonding environment was vacuum, and the bonding temperature was the room temperature.

A first thinning treatment was performed on the second wafer 2 to obtain a composite wafer 5. The first thinning treatment was grinding thinning, and the grinding thinning was carried out in two steps, wherein the first time was coarse thinning by a coarse grinding wheel, and the second time was fine thinning by a fine grinding wheel, wherein a thickness of the single-crystal functional layer 4 obtained after the thinning treatment was slightly larger than a preset thickness.

The chemical-mechanical polishing was performed on the surface of the obtained single-crystal functional layer 4, wherein a thickness of the quartz layer after the chemical-mechanical polishing was controlled to be 2μm, and the surface roughness Ra was smaller than 0.7nm.

The piezoelectric wafer 6 was washed, wherein the piezoelectric wafer 6 was a double-polished 42° Y-X lithium tantalate wafer.

The second bonding was performed between one side of the single-crystal functional layer 4 of the composite wafer 5 and the piezoelectric wafer 6. The second bonding was performed by using the high-vacuum surface-activation bonding method, wherein the bonding environment was vacuum, and the bonding temperature was the room temperature.

A second thinning treatment was performed on the piezoelectric wafer 6 to obtain a piezoelectric layer 8. The second thinning treatment was grinding thinning, and the grinding thinning was carried out in two steps, wherein the first time was coarse thinning by the coarse grinding wheel, and the second time was fine thinning by the fine grinding wheel, wherein the thickness of the piezoelectric wafer obtained after the thinning treatment was slightly larger than the preset thickness.

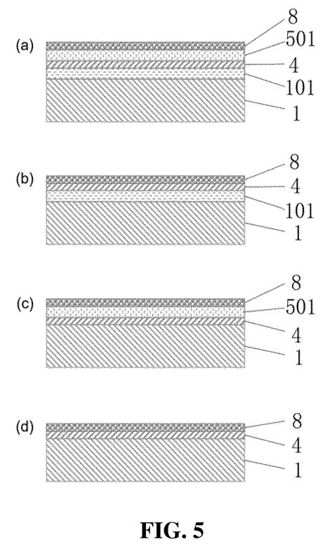

The chemical-mechanical polishing was performed on the surface of the piezoelectric layer 8, wherein a thickness of the piezoelectric layer 8 after the chemical-mechanical polishing was controlled to be 800nm, and the surface roughness Ra was smaller than 0.5nm. The composite substrate was obtained, as shown in (d) in FIG. 5.

### Example 2

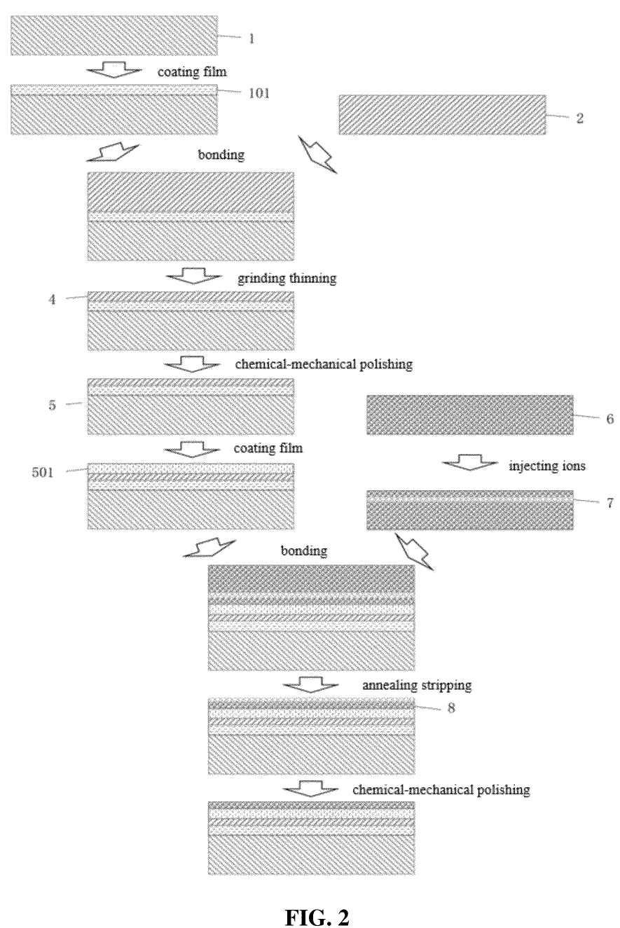

The present embodiment provided a preparation method for the composite substrate, as shown in FIG. 2 (the middle layer 101 was not prepared), wherein the preparation method was as follows.

The first wafer 1 and the second wafer 2 were washed, wherein the first wafer 1 was a single-polished high-resistance silicon wafer, and the second wafer 2 was a double-polished AT-cut quartz wafer.

The first bonding was performed between the first wafer 1 and the second wafer 2. The first bonding was performed by using the plasma activation bonding method, i.e., the oxygen plasma was used to irradiate the bonding surfaces of the first wafer 1 and the second wafer 2 to activate the surfaces; then two bonding surfaces were attached to realize the pre-bonding; and the bonding was finished by the low-temperature annealing, wherein the bonding environment was vacuum, and the bonding temperature was 150°C.

The first thinning treatment was performed on the second wafer 2 to obtain a composite wafer 5. The first thinning treatment was the grinding thinning, and the grinding thinning was carried out in two steps, wherein the first time was coarse thinning by the coarse grinding wheel, and the second time was fine thinning by the fine grinding wheel, wherein the thickness of the single-crystal functional layer 4 obtained after the thinning treatment was slightly larger than the preset thickness.

The chemical-mechanical polishing was performed on the surface of the obtained single-crystal functional layer, wherein the thickness of the quartz layer after the chemical-mechanical polishing was 10μm, and the surface roughness Ra was smaller than 0.7nm.

A middle layer 501 was prepared on the surface of the single-crystal functional layer 4. Specifically, a silicon dioxide film was prepared by using a magnetron sputtering process, wherein a thickness of the coating film was slightly thicker than 5μm; and the surface of the silicon dioxide film was treated by using the chemical-mechanical polishing process, wherein a thickness of the silicon dioxide film was controlled to be 5μm, and the surface roughness Ra was smaller than 0.5nm.

The piezoelectric wafer 6 was washed, wherein the piezoelectric wafer 6 was a double-polished Z-X lithium niobate wafer.

The ion injection process was performed, wherein the injected ions were helium ions; the ion injection energy was 230 keV; and the ion injection dosage was 6 × 10¹⁶ ions/cm², so as to generate an ion damage layer 7 inside the piezoelectric wafer.

The second bonding was performed between one side of the middle layer 501 of the composite wafer 5 and the piezoelectric wafer 6. The second bonding was performed by using the high-vacuum surface-activation bonding method, wherein the bonding environment was vacuum, and the bonding temperature was the room temperature.

The second thinning treatment was performed on the piezoelectric wafer 6 to obtain the piezoelectric layer 8. The second thinning treatment was annealing and stripping. The annealing was performed twice, wherein the first annealing was in a nitrogen atmosphere; an annealing temperature was 200°C; an annealing duration was 3h; the second annealing was in the nitrogen atmosphere, an annealing temperature was 400°C; and an annealing duration was 6h.

The chemical-mechanical polishing was performed on the surface of the piezoelectric layer 8, wherein the thickness of the piezoelectric layer 8 after the chemical-mechanical polishing was controlled to be 600nm, and the surface roughness Ra was smaller than 0.5nm. The composite substrate was obtained, as shown in (c) in FIG. 5.

### Example 3

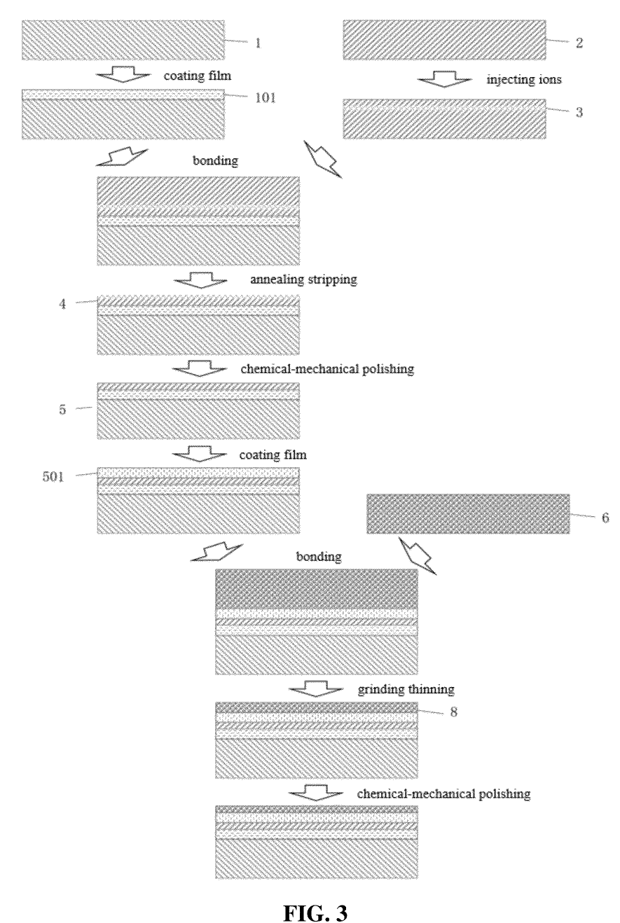

The present embodiment provided a preparation method for the composite substrate, as shown in FIG. 3 (the middle layer 501 was not prepared), wherein the preparation method was as follows.

The first wafer 1 and the second wafer 2 were washed, the first wafer 1 was a double-polished 4H silicon carbide wafer, and the second wafer 2 was a double-polished ST-cut quartz wafer.

The middle layer 101 was prepared on the surface of the first wafer 1. Specifically, the silicon dioxide film was prepared by using the magnetron sputtering process, wherein the thickness of the coating film was slightly thicker than 5μm; and the surface of the silicon dioxide film was treated by using the chemical-mechanical polishing process, wherein the thickness of the silicon dioxide film was controlled to be 5μm, and the surface roughness Ra was smaller than 0.5nm.

The ion injection process was performed, wherein the injected ions were hydrogen ions; the ion injection energy was 180 keV; and the ion injection dosage was 8×10¹⁶ ions/cm², so as to generate an ion damage layer 3 inside the second wafer 2.

The first bonding was performed between one side of the middle layer 101 of the first wafer 1 and the second wafer 2. The first bonding was performed by using the plasma activation bonding method, wherein the bonding environment was vacuum, and the bonding temperature was 150°C.

The first thinning treatment was performed on the second wafer 2 to obtain the composite wafer 5. The first thinning treatment was annealing and stripping. The annealing was performed twice, wherein the first annealing was in the nitrogen atmosphere; the annealing temperature was 180°C; the annealing duration was 4h; the second annealing was in the nitrogen atmosphere, the annealing temperature was 350°C; and the annealing duration was 8h.

The chemical-mechanical polishing was performed on the surface of the obtained single-crystal functional layer 4, wherein the thickness of the quartz layer 4 after the chemical-mechanical polishing was 1 μm, and the surface roughness Ra was smaller than 0.7nm.

The piezoelectric wafer 6 was washed, wherein the piezoelectric wafer was the double-polished Z-X lithium niobate wafer.

The second bonding was performed between one side of the single-crystal functional layer 4 of the composite wafer 5 and the piezoelectric wafer 6. The second bonding was performed by using the high-vacuum surface-activation bonding method, wherein the bonding environment was vacuum, and the bonding temperature was the room temperature.

The second thinning treatment was performed on the piezoelectric wafer 6 to obtain the piezoelectric layer 8. The second thinning treatment was grinding thinning, and the grinding thinning was carried out in two steps, wherein the first time was coarse thinning by the coarse grinding wheel, and the second time was fine thinning by the fine grinding wheel, wherein the thickness of the single-crystal functional layer obtained after the thinning treatment was slightly larger than the preset thickness.

The chemical-mechanical polishing was performed on the surface of the piezoelectric layer 8, wherein the thickness of the piezoelectric layer 8 after the chemical-mechanical polishing was controlled to be 2μm, and the surface roughness Ra was smaller than 0.5nm. The composite substrate was obtained, as shown in (b) in FIG. 5.

### Example 4

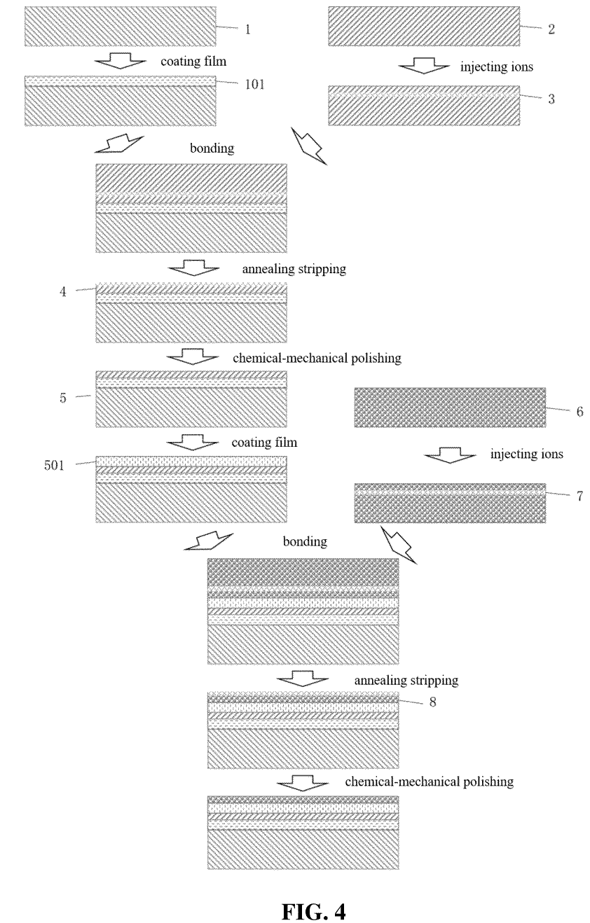

The present embodiment provided a preparation method for the composite substrate, as shown in FIG. 4, wherein the preparation method was as follows.

The first wafer 1 and the second wafer 2 were washed, the first wafer 1 was a single-polished high-resistance silicon wafer, and the second wafer 2 was a double-polished ST-cut quartz wafer.

The middle layer 101 was prepared on the surface of the first wafer 1. Specifically, the silicon dioxide film was prepared by using the magnetron sputtering process, wherein the thickness of the coating film was slightly thicker than 2μm; and the surface of the silicon dioxide film was treated by using the chemical-mechanical polishing process, wherein the thickness of the silicon dioxide film was controlled to be 2μm, and the surface roughness Ra was smaller than 0.5nm.

The ion injection process was performed, wherein the injected ions were hydrogen ions; the ion injection energy was 150 keV; and the ion injection dosage was 6×10¹⁶ ions/cm², so as to generate the ion damage layer 3 inside the second wafer 2.

The first bonding was performed between one side of the middle layer 101 of the first wafer 1 and the second wafer 2. The first bonding was performed by using the plasma activation bonding method, wherein the bonding environment was vacuum, and the bonding temperature was 150°C.

The first thinning treatment was performed on the second wafer 2 to obtain the composite wafer 5. The first thinning treatment was annealing and stripping. The annealing was performed twice, wherein the first annealing was in the nitrogen atmosphere; the annealing temperature was 180°C; the annealing duration was 4h; the second annealing was in the nitrogen atmosphere, the annealing temperature was 350°C; and the annealing duration was 8h.

The chemical-mechanical polishing was performed on the surface of the obtained single-crystal functional layer 4, wherein the thickness of the quartz layer 4 after the chemical-mechanical polishing was 800nm, and the surface roughness Ra was smaller than 0.7nm.

The middle layer 501 was prepared on the surface of the single-crystal functional layer 4. Specifically, the silicon dioxide film was prepared by using the magnetron sputtering process, wherein the thickness of the coating film was slightly thicker than 1μm; and the surface of the silicon dioxide film was treated by using the chemical-mechanical polishing process, wherein the thickness of the silicon dioxide film was controlled to be μm, and the surface roughness Ra was smaller than 0.5nm.

The piezoelectric wafer 6 was washed, wherein the piezoelectric wafer was the double-polished X-Z lithium niobate wafer.

The ion injection process was performed, wherein the injected ions were helium ions; the ion injection energy was 300 keV; and the ion injection dosage was 6 × 10¹⁶ ions/cm², so as to generate the damage layer 7 inside the piezoelectric wafer 6.

The second bonding was performed between one side of the middle layer 501 of the composite wafer 5 and the piezoelectric wafer 6. The second bonding was performed by using the high-vacuum surface-activation bonding method, wherein the bonding environment was vacuum, and the bonding temperature was the room temperature.

The second thinning treatment was performed on the piezoelectric wafer 6 to obtain the piezoelectric layer 8. The second thinning treatment was the annealing and stripping. The annealing was performed twice, wherein the first annealing was in the nitrogen atmosphere; the annealing temperature was 200°C; the annealing duration was 3h; the second annealing was in the nitrogen atmosphere, the annealing temperature was 400°C; and the annealing duration was 6h.

The chemical-mechanical polishing was performed on the surface of the piezoelectric layer 8, wherein the thickness of the piezoelectric layer 8 after the chemical-mechanical polishing was controlled to be 800nm, and the surface roughness Ra was smaller than 0.5nm. The composite substrate was obtained, as shown in (a) in FIG. 5.

In the composite substrates prepared by Examples 1-4, the piezoelectric layers are all in the single-crystal state, and they have the excellent acoustic-electric property and electro-optic property like ordinary lithium-tantalate or lithium-niobate single-crystal substrates, so as to ensure that the composite substrate can be used in the acoustic-electric devices and the electro-optic devices. Besides playing a supporting role, the support substrate can also improve quality factor of the device, realize the waveguide effect, and accelerate the heat dissipation of the device. The composite substrate has a higher transmission efficiency and a lower transmission loss during the electro-optic and acoustic-electric transmission processes by realizing the waveguide effect. The single-crystal functional layer is better compared with the polycrystalline layer formed by the coating process commonly used in the prior art, and the single-crystal functional layer can realize the anisotropy and the precise regulation, so as to solve problems still existing in the prior art, such as the spurious response in transverse modes.

The applicant declares that the present illustrates the detailed structure features of the present by the above embodiments, but the present disclosure is not limited to the above detailed structure features, i.e., it does not mean that the present disclosure must be relied on the above detailed structure features in order to be implemented. It should be clear to those skilled in the art that any improvement of the present disclosure, equivalent replacement of the selected components of the present disclosure, the addition of auxiliary components, and the selection of a specific method, etc., all fall within the scope of protection and disclosure of the present disclosure.

The preferred embodiments of the present disclosure are described in detail above, however, the present disclosure is not limited to the specific details in the above embodiments. Within the scope of the technical conception of the present disclosure, a variety of simple variations of the technical solutions of the present disclosure can be carried out, and all of these simple variations fall within the scope of protection of the present disclosure.

It is also to be noted that the various specific technical features described in the above specific embodiments can be combined in any suitable manner without conflict, and in order to avoid unnecessary repetition, the present disclosure does not separately describe the various possible combinations.

Additionally, any combination of different embodiments of the present disclosure may also be made when they are not contrary to the idea of the present disclosure, and they should also be regarded as contents disclosed by the present disclosure.

1. A preparation method for a composite substrate, wherein the preparation method comprises:
performing first bonding between a first wafer and a second wafer, and performing a first thinning treatment on the second wafer to obtain a composite wafer; and
performing second bonding between one side of the second wafer of the composite wafer and a piezoelectric wafer, and performing a second thinning treatment on the piezoelectric wafer to obtain the composite substrate,
wherein the first wafer is a substrate wafer, and the second wafer is a single-crystal functional layer,
wherein the single-crystal functional layer is a quartz having a specific cutting angle,
wherein the first wafer is made of any one of high-resistance silicon, sapphire, spinel, silicon carbide, and diamond, and
wherein the quartz having a specific cutting angle is any one of a double-polished 69°Y-90°X quartz wafer, a double-polished AT-cut quartz wafer and a double-polished ST-cut quartz wafer.

2. The preparation method according to claim 1, wherein at least one middle layer is prepared on one side of the first wafer before the first bonding.

3. The preparation method according to claim 2, wherein the first bonding is performed between the second wafer and one side of the middle layer of the first wafer.

4. The preparation method according to claim 1, wherein the first thinning treatment comprises:
injecting ions at one side of the second wafer before the first bonding, so as to obtain an ion damage layer;
performing the first bonding between one side of the ion damage layer of the second wafer and the first wafer; and
annealing and stripping after the first bonding.

5. The preparation method according to claim 1, wherein the first thinning treatment comprises: performing grinding thinning for the first wafer after the first bonding.

6. The preparation method according to claim 1, wherein at least one middle layer is prepared on one side of the second wafer before the second bonding.

7. The preparation method according to claim 1, wherein the second thinning treatment comprises:
injecting ions at one side of the piezoelectric wafer before the second bonding, so as to obtain an ion damage layer;
performing the second bonding between one side of the ion damage layer of the piezoelectric wafer and the composite wafer; and
annealing and stripping after the second bonding.

8. The preparation method according to claim 1, wherein the second thinning treatment comprises: performing grinding thinning for the piezoelectric wafer after the second bonding.

9. A composite substrate, wherein the composite substrate is prepared by the preparation method for the composite substrate according to claim 1.
